(19) United States
(12) Patent Application Publication
(10) Pub. No.: US 2012/0199174 A1
(43) Pub. Date: Aug. 9, 2012

(54) Recycled air photovoltaic cooler

(76) Inventor: Duncan M. Morris, Las Vegas, NV (US)

(21) Appl. No.: 12/931,547

(22) Filed: Feb. 4, 2011

(51) Int. Cl. H01L 31/052

(52) U.S. Cl. 136/246

(57) ABSTRACT

This invention takes the conditioned cool air from inside the structure and moves it across the solar panels to cool them into a higher state of electrical production. Air then returns to structures cooling system and then back into the structure. Also, invention will supply warm air into structure during winter months.

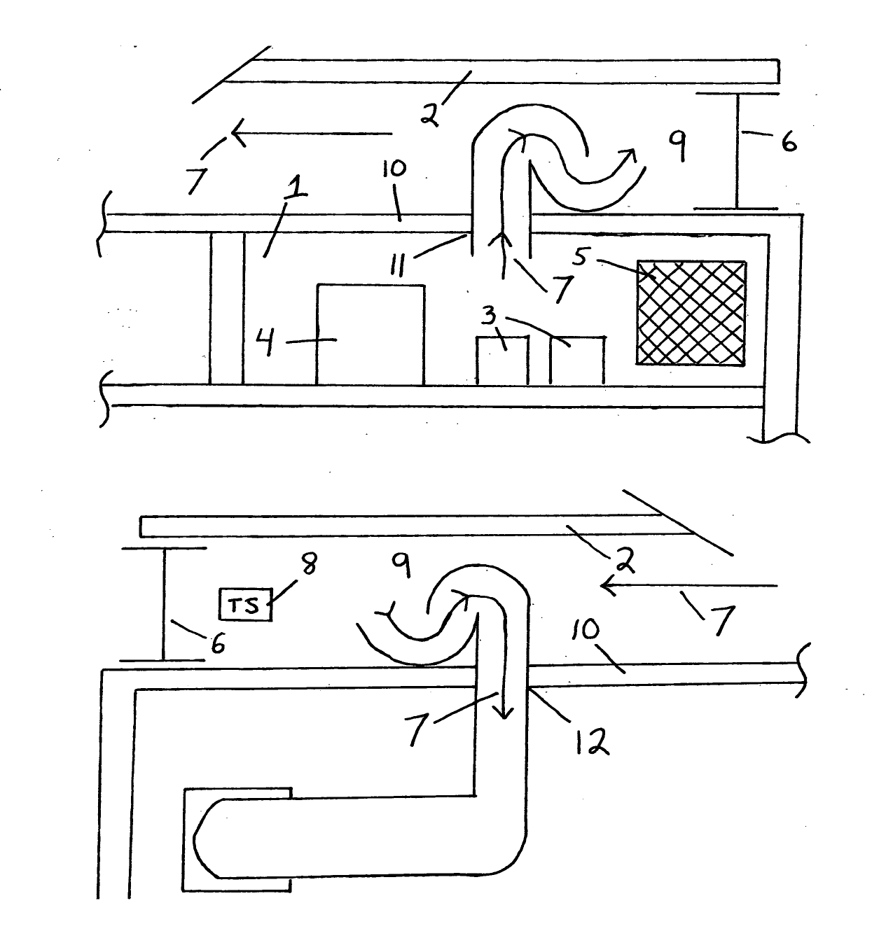

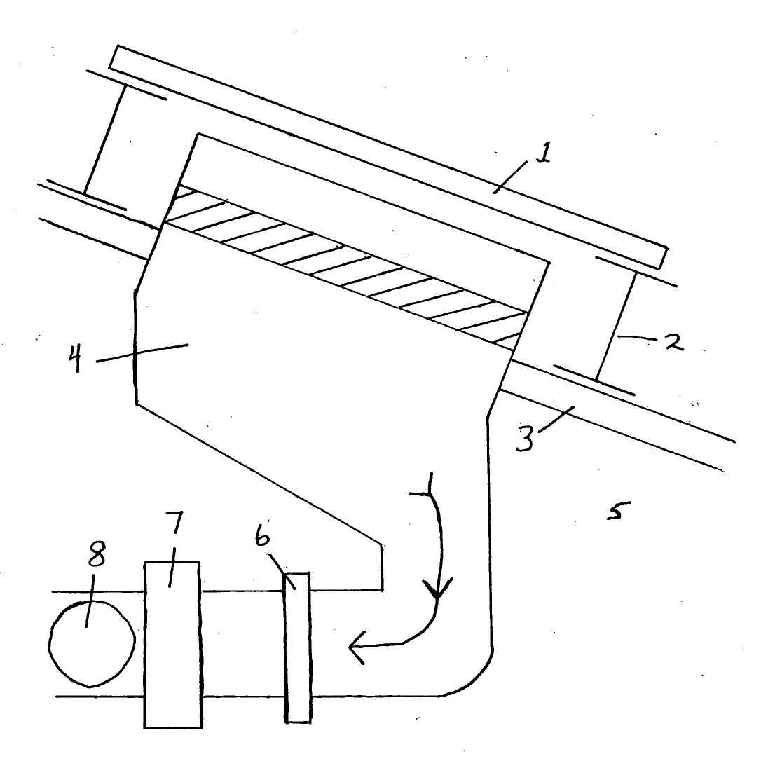

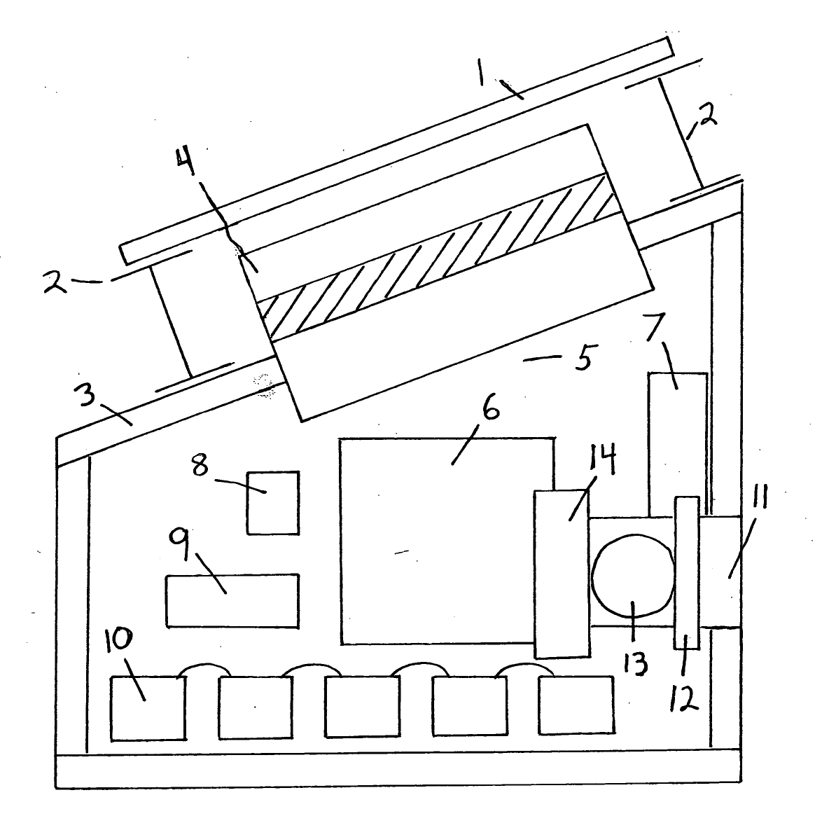

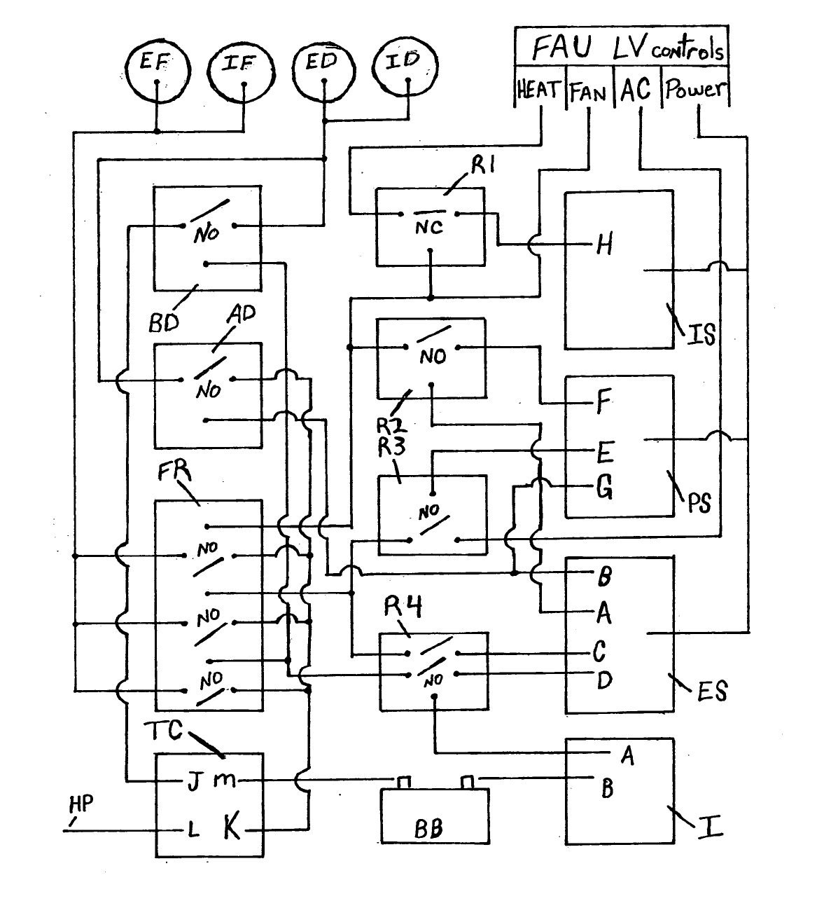

### INVENTION BACKGROUND

In 2001, I Duncan Morris, had begun to research into the installation of Solar Panels on my house. I soon discovered the main inefficiency of Photovoltaic Solar Panels was heat and further investigation had resulted in the findings that active cooling was not very efficient. Most of the Southwest North American Continent receives ample amounts of solar radiation, yet none is usable during the summer months. This invention will utilize the preconditioned air inside residential and commercial buildings to cool the Photovoltaic Panels mounted on the structure.

### INVENTION SUMMARY

Photovoltaic Solar Panels operate at an optimum temperature of 78° F. During the summer months in the Southwest desert, temperatures can exceed 105° F. in the shade. Roof mounted PV panels will exceed 140° F. exposed to direct sunlight and will produce no electricity. The main objective of this invention is to use the preconditioned air inside the structure, the optimum temperature of 70° to 80° F. has already been achieved. By circulating this air beneath the PV panels, the temperature can be brought into a range of temperature that will allow the production of electricity. Technology has progressed to the point where active cooling is becoming feasible, and this system will use the existing cool air to actively cool the PV panels. This is where the name Recycled Air Photovoltaic Cooler comes from. The new system will tie directly into the existing system, therefore the air that is drawn out of the structure will cool the PV panels and then go directly into the air return of the FAU to be reconditioned and circulated back into the structure.

### DRAWING DESCRIPTION

Drawing I shows Photovoltaic Panels mounted on roof top, with air flow direction and enclosed areas. Roof penetrations with duct work designed to prevent moisture from entering structure.

Drawing II shows air flow from PV Envelope (PVE) back into structure.

Drawing III shows air flow from structure into Enclosed Electronics Envelope (EEE) and then into the PVE.

Drawing IV shows wiring diagram and controls for system functions.

### DETAILED DESCRIPTION

### Drawing I

1 The Enclosed Electrical Envelope (EEE) This area is the first area the recycled air will enter, via 5 the supply fan. The air entering this envelope will be between 70° F. and 80° F. and is drawn directly from the interior of the structure. The main purpose of the EEE is to continuously cool all vital electronics (i.e. Inverter, battery bank, relays and astronomical time clock). It is a major part of this system to provide a controlled environment for all electrical production 2, storage 3, inversion 4, and use 5. Operation of electrical equipment at extreme temperatures is inefficient and potentially detrimental to the equipment, the EEE will eliminate this problem in the desert climate.

2 These are the Photovoltaic Solar Panels that are mounted on an aluminum I beam 6 and create the top of the Solar Panel Cooling Envelope 9.

3 Battery Bank—Designed for minimal electrical storage, will only operate Astronomical time clock. Allowing the system to suffer grid power outage and still remain operational.

4 Inverter—Regulates battery charge and inverts DC voltage to AC voltage and syncs electrical sign wave to grids sign wave for produced electricity supply to grid.

5 Supply Fan—Will draw in filtered air from structure interior and force cool air into Solar Panel Cooling Envelope (SPCE) 9.

6 Aluminum I Beam—Will supply the four wall enclosure of the SPCE and support for the Photovoltaic Solar Panels 2.

7 Air Flow—Arrows indicate air flow direction in enclosed areas. Air flow is given by operation of Supply Fan 5 and Return Fan (drawing II 7).

8 Thermostat—Solar thermostat placed at the return side of the SPCE and will control exhaust dampers during heat overload or air conditioning at FAU.

9 Solar Panel Cooling Envelope—Area sealed off from exterior and will contain air flow from structure and EEE controlling the temperature of the PV Solar Panels. Will also be used during the winter months to supply interior of structure with warm air (drawing IV R1).

10 Roof Line—Shows top of structure where system will be mounted. Roof line also creates the bottom portion of the SPCE.

11 Supply Penetration—Created for air flow from EEE to SPCE, duct work is designed to prevent moister back flow into structure or EEE.

12 Return Penetration—Created for air flow from SPCE to structures FAU, duct work is designed to prevent moister back flow into the structure.

### Drawing II

1 PV Solar Panels—Forms top of SPCE to contain air flow.

2 Aluminum I Beams—Forms sides of SPCE and acts as supports for PV Solar Panel mounting.

3 Roof Line—Shows where return air ducts 4 penetrate from SPCE into structure and return into building via Air Filter 6 and Return Fan 7.

4 Return Air Duct—The return duct brings air flow directly back to the FAU to be cooled and delivered back into the structure.

5 Attic Space—Area where return air duct will be concealed from view.

6 Air Filter—Installed directly into air duct, will prevent foreign contaminants from clogging Return Fan 7.

7 Return Fan—Installed directly into air duct, will assist in the movement of air flow thru the system.

8 Return Damper—Operates in extreme heat to ventilate system instead of trying to cool heated air. Operation will coincide with intake damper (drawing III 13).

### Drawing III

1 PV Solar Panels—Form top of SPCE to and contain air flow.

2 Aluminum I Beams—Form sides of SPCE and acts as supports for Solar Panels.

3 Roof Line—Shows supply air duct penetrations and acts as bottom for SPCE.

4 Supply Air Duct—shows roof line penetration from EEE and will allow air flow but also prevent moister from flowing back into EEE.

5 Enclosed Electrical Envelope (EEE)—Area inside attic space, specifically closed air tight to house all electrical equipment. Keeping all vital electrical components at optimum operation temperatures during the summer months will prolong the life of equipment.

6 Access Door—Allows entrance into the EEE from the attic structure.

7 Inverter—Receives DC current from PV panels directs it to charge of battery bank or supplies the power to the grid.

8 Time Clock—Astronomical Time Clock will be used, as operation in hot summer months requires a purging of the SPCE.

9 Relay Enclosure—The National Electrical Code requires that these type of electrical operations be in an approved enclosure.

10 Battery Bank—Will be used for the powering of the Astronomical Time clock only.

11 Air Intake—Supplies air from structure into the EEE.

12 Air Filter—Cleans air from structure or exterior before it gets to intake fan and enters the EEE.

13 Intake Damper—Operates in extreme temperatures to properly ventilate SPCE before the recycling process begins.

14 Intake Fan—Moves air into the EEE and will force the cool air into the SPCE.

### Drawing IV

Electrical Wiring Diagram—will show operations of invention as well as controls.

| | |
|---|---|
| IF | Intake Fan |
| EF | Exhaust Fan |
| ID | Intake Damper |
| ED | Exhaust Damper |
| HP | House Power |
| FR | Fan Relays |
| AD | Cool Temperature Relay |
| BD | Hot Temperature Relay |
| TC | Astronomical Time Clock |
| BB | Battery Bank |
| R1 | Heater Relay |
| R2 | Warm Air Relay |
| R3 | Cool Air Relay |
| R4 | System Shunt Relay |
| I | Inverter |
| IS | Interior Thermostat |
| PS | Solar Panel Thermostat |
| ES | Exterior Thermostat |

IS H thru R1 is controlled by ES A below 60° F. Interior thermostat calls for heat, R1 is normally closed and will allow FAU to turn on, for normal control.

IS I Allows for interior to call for Air Conditioning with no interruption from invention.

PS E operates R3 when SPCE reaches a temperature 80° F. or greater.

PS F operates IF EF R1 and FAU Fan when SPCE temperature is 70° F. or greater.

PS G operates BD when SPCE exceeds a temperature of 110° F.

ES A operates R2 when exterior temperature is below 60° F., and will allow warm air to flow from SPCE when IS H calls for heat inside the structure.

ES B operates BD when temperature exceeds 90° F.

ES C operates FR when temperature exceeds 80° F., and will also coincide operations with PS E thru R3 to operate structures air conditioning system.

ES D operates AD and FR when exterior temperatures are between 70° F. and 80° F.

I A operates R4 when an overcast day or rain prevents solar panels from creating electricity, R4 will no longer receive a voltage signal from inverter and will cut off operations to prevent waste.

I B Inverter charge voltage to BB and TC.

R4 is a system control relay that will discontinue all invention operations in the event of a cloudy or rainy day.

R3 is controlled by PS E and will allow the operation of structures air conditioning unit by the invention thru ES C.

R2 is controlled by ES A and will allow the circulation of warm air into the structure from the SPCE provided that the signal from PS F is present.

R1 will disconnect IS H signal when R2 is activated, and not allow the FAU heater to engage, but draw warm air into the structure when available.

BB will insure proper time and operation at TC.

TC J will supply power to BD from house power on a 2 hour time cut off after sunrise to vent excessive heat at morning start up during hot summer months.

TC K supplies power to AD and FR, turns on at sunrise and terminates at sunset.

TC L line side voltage for operations of IF, EF, ID and ED. 20 amp at 120 volts

TC M power supply for time clock operation, voltage can vary depending on BB.

BD relay is activated by ES or PS. Dampers ID and ED will open and allow venting of hot air during summer months.

AD relay is activated by R4 and ES. Dampers ID and ED will open and allow venting of warm air during spring and fall months.

FR will operate IF and EF to allow circulation of air under solar panels. This relay is controlled at several different locations, any one of three controls will turn these fans on.

1 The use of this invention will bring the actual production level of electricity up in the Southwest desert area of North America. Because of the extreme high temperatures during the summer months a great deal of energy producing daylight is lost. Energy is already burned to cool the inside of the structure and recycling the cool air will create a double use of energy and will be compensated by the production of more energy.
